(19) United States
(12) Patent Application Publication
(10) Pub. No.: US 2026/0157185 A1
(43) Pub. Date: Jun. 4, 2026

(54) SEMICONDUCTOR DEVICE AND METHOD FOR FORMING THE SAME

(71) Applicant: TAIWAN SEMICONDUCTOR MANUFACTURING COMPANY LTD., HSINCHU (TW)

(72) Inventors: WEI-YU CHOU, HSINCHU (TW); YANG-CHE CHEN, HSIN-CHU CITY (TW); MING JUN LI, NEW TAIPEI CITY (TW); HSIANG-TAI LU, HSINCHU COUNTY (TW); WEI-RAY LIN, HSINCHU CITY (TW)

(21) Appl. No.: 18/967,695

(22) Filed: Dec. 4, 2024

(51) Int. Cl. H01L 23/60; H01L 21/66; H01L 23/00

(52) U.S. Cl. CPC H10W 42/60; H10P 74/273; H10W 42/00; H10W 42/121

(57) ABSTRACT

A semiconductor device includes a substrate, a seal ring, sensing devices, conductive towers, and an insulation layer. The substrate has a circuit region and a peripheral region around the circuit region. The seal ring is formed over the substrate and disposed in the peripheral region. The sensing devices are formed over the substrate and disposed between the seal ring and the circuit region. The conductive towers are formed over the substrate and disposed between the seal ring and the sensing devices. The conductive towers are configured to provide discharge paths for the sensing devices. The insulation layer is formed over the substrate. The seal ring, the sensing devices and the conductive towers are formed within the insulation layer.

### BACKGROUND

In electronics, an integrated circuit (IC) is a miniaturized electronic circuit (including semiconductor devices as well as passive components) that has been manufactured in the surface of a thin substrate of semiconductor material. In general, wafers are used as carriers for semiconductor fabrication during the production of integrated circuits (ICs). After semiconductor fabrication processes, a plurality of dies are formed on a wafer, and the wafer is sawed into individual chips once the fabrication is complete. The sawing process may damage the die, such as causing cracks into a chip region. Sensor has been used to detect the cracks as a damage indicator. However, the sensor is often electrically floating during certain manufacturing stages. These process-induced charges that are easily accumulated in the floating sensor may lead to electrical over stress (EOS) burn-out.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic top view of a semiconductor device in accordance with some embodiments of the present disclosure.

FIG. 2 is an enlarged view of the indicated section shown in FIG. 1, in accordance with some embodiments of the present disclosure.

FIG. 3A is a schematic top view of the semiconductor device in the enhanced region of FIG. 2, in accordance with some embodiments of the present disclosure.

FIG. 3B is a schematic cross-sectional view of the semiconductor device taken along line C1-C1 in FIG. 3A, in accordance with some embodiments of the present disclosure.

FIG. 4A is a schematic cross-sectional view of a semiconductor device in accordance with some embodiments of the present disclosure.

FIG. 4B is a schematic cross-sectional view of a semiconductor device in accordance with some embodiments of the present disclosure.

FIG. 4C is a schematic cross-sectional view of a semiconductor device in accordance with some embodiments of the present disclosure.

FIG. 5A is a schematic top view of the semiconductor device in the enhanced region of FIG. 2, in accordance with some embodiments of the present disclosure.

FIG. 5B is a schematic cross-sectional view of the semiconductor device taken along line C2-C2 in FIG. 5A, in accordance with some embodiments of the present disclosure.

FIG. 5C is an enlarged top view of a capacitor structure in FIG. 5A.

FIG. 6 is a schematic top view of the semiconductor device in the enhanced region of FIG. 2, in accordance with some embodiments of the present disclosure.

FIG. 7A is a schematic top view of the semiconductor device in the enhanced region of FIG. 2, in accordance with some embodiments of the present disclosure.

FIG. 7B is a schematic cross-sectional view of the semiconductor device taken along line C3-C3 in FIG. 7A, in accordance with some embodiments of the present disclosure.

FIG. 8A is a schematic top view of the semiconductor device in the enhanced region of FIG. 2, in accordance with some embodiments of the present disclosure.

FIG. 8B is a schematic top view of the enhanced region in FIG. 2, in accordance with some embodiments of the present disclosure.

FIG. 9A shows equivalent circuits of the sensing devices and the capacitors surrounding the outside of the circuit region, in accordance with some embodiments of the present disclosure.

FIG. 9B shows equivalent circuits in one of the repeating units of FIG. 9A, in accordance with some embodiments of the present disclosure.

FIG. 10A shows equivalent circuits of the sensing devices and the capacitors surrounding the outside of the circuit region, in accordance with some embodiments of the present disclosure.

FIG. 10B shows equivalent circuits in one of the repeating units of FIG. 10A, in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “under,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Generally, semiconductor devices are typically manufactured on a wafer. A wafer includes a plurality of dies, each die separated by scribe lines. Each die may include one or more seal rings forming an electrical and mechanical seal surrounding the various devices and circuits on the die. Once the fabrication of the integrated circuit on the wafer is complete, the wafer is divided into many chips, typically by conventional mechanical or laser sawing methods along the scribe lines. The seal rings can provide structural reinforcement and stop moisture and mobile ionic contaminants from entering a circuit region of a chip and improving the operational reliability.

It has been known that the sawing process may damage the die. In particular, the mechanical stress caused by the saw can result in cracks and delamination in the die. A typical problem is that low-k dielectric materials of an insulating layer for encapsulating interconnection features (such as seal rings and other metal lines) are prone to damage incurred by stress introduced by the sawing process. When cracks form in the insulating layer, interconnection features in the low-k dielectric materials may be damaged. If the cracks become sufficiently serious, performance degradation or total device failure can result, particularly if the defects penetrate the seal ring of the device. There have been attempts for detecting defects, such as cracks and delamination in the semiconductor device.

Sensing devices each configured as a daisy chain structure are integrated in the region between the seal ring and a circuit region. The daisy chain structures are arranged to surround the circuit region. When there is mechanical damage to the seal ring and the circuit region, it breaks daisy chain, inducing open signal as a damage indicator. Thus, those sensing devices for detecting crack defects in a semiconductor device can also be referred to as seal ring crack sensors. However, these sensing devices are often electrically floating during certain stages, such as mechanical testing or production, prior to their connection with protective circuits. These process-induced charges are easily accumulated in these floating sensing devices. Excessive charge accumulation can lead to electrical over stress (EOS), which may result in the failure of the sensing devices. For example, when charges flow into the sensing device and flow out of the sensing device, it usually induces a high current, and the bottom of the sensing device may be burned out, which induces an unwanted open signal and introduces false judgement of mechanical damage.

Embodiments of the present disclosure provide a semiconductor device and a method for forming the semiconductor device. The semiconductor device includes at least a capacitor integrated with a sensing devices. In some embodiments, the semiconductor device includes sensing devices and conductive towers. The conductive towers are configured to provide discharge paths for the sensing devices. In some embodiments, the semiconductor device effectively prevents excessive charges from flowing into the sensing devices and burning the bottoms of the sensing devices. Accordingly, the EOS risk that often occurred in the conventional seal ring sensors can be greatly reduced.

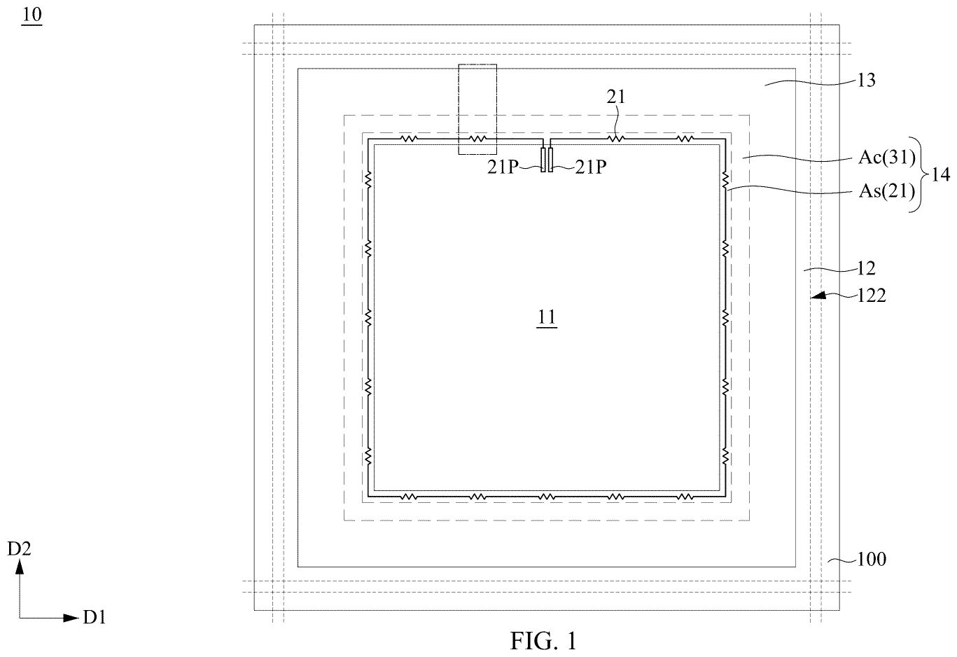

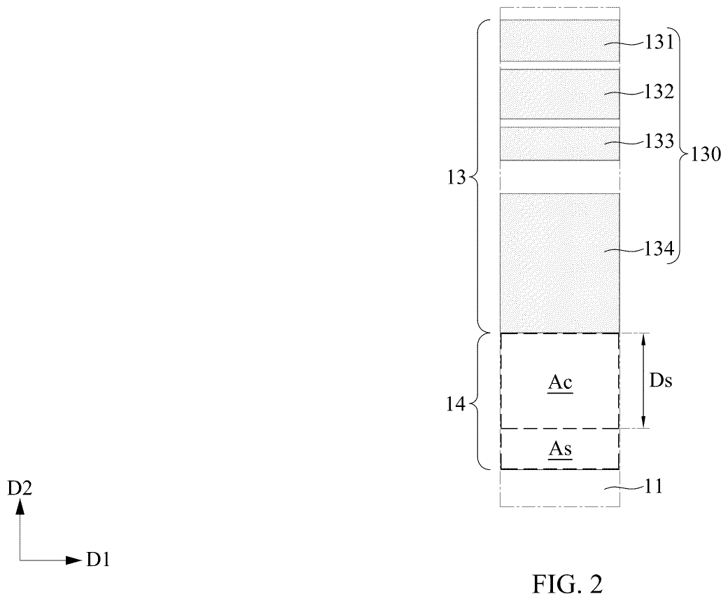

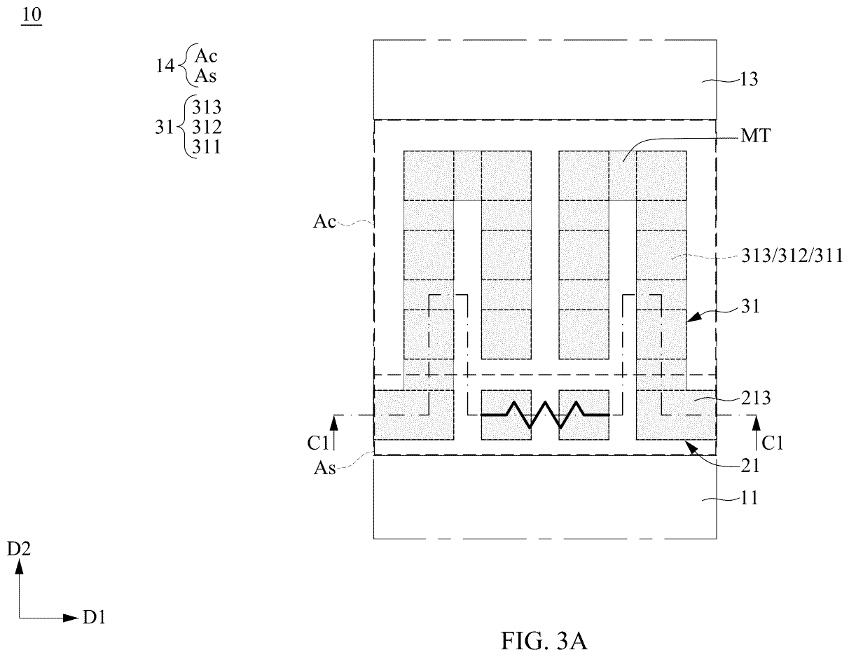

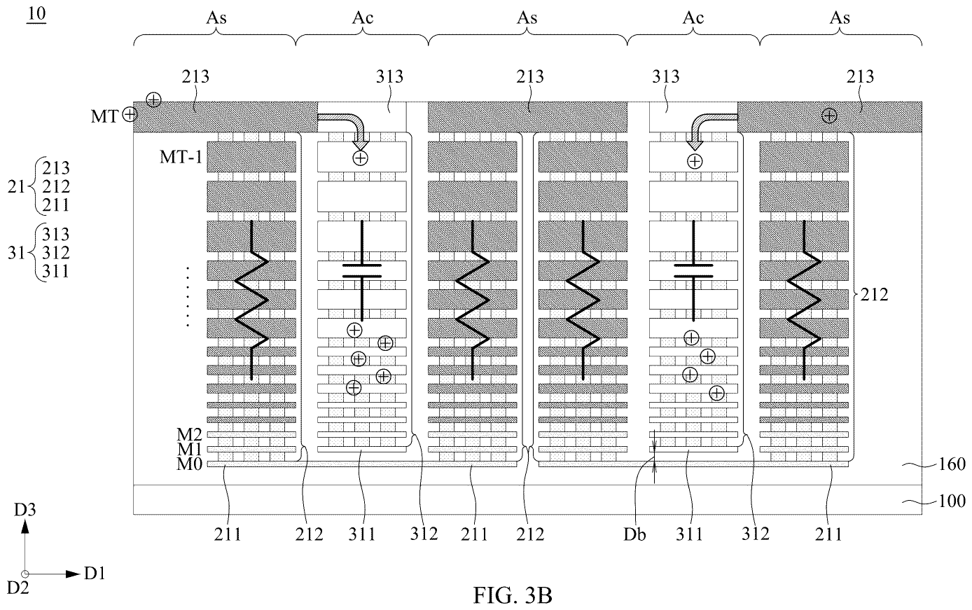

FIG. 1 is a schematic top view of a semiconductor device 10 in accordance with some embodiments of the present disclosure. FIG. 2 is an enlarged view of the indicated section shown in FIG. 1. FIG. 3A is a schematic top view of the semiconductor device in the enhanced region 14 of FIG. 2. FIG. 3B is a schematic cross-sectional view of the semiconductor device taken along line C1-C1 in FIG. 3A.

Referring to FIG. 1 to FIG. 3B, in some embodiments, a semiconductor device 10 includes a substrate 100, a seal ring 130, several sensing devices 21, several conductive towers 31 and an insulation layer 160. The substrate 100 has a circuit region 11 and a peripheral region 12 around the circuit region 11. In some embodiments, the peripheral region 12 includes a seal ring region 13 and an enhanced region 14 (FIG. 2). The seal ring 130 is formed over the substrate 100 and disposed in the seal ring region 13 of the peripheral region 12. In some embodiments, the semiconductor device 10 further includes several sensing devices 21 and several conductive towers 31 formed over the substrate 100 and disposed in the enhanced region 14. The enhanced region 14 includes a sensor region As and a capacitor region Ac. In addition, the sensing devices 21 may be disposed between the seal ring 130 and the circuit region 11. The conductive towers 31 may be disposed between the sensing devices 21 and the seal ring 130 in the seal ring region 13. As shown in FIG. 2, the sensing devices 21 are arranged in the sensor region As, and the conductive towers 31 are arranged in the capacitor region Ac. In addition, the insulation layer 160 (FIG. 3B) is formed over the substrate 100. The seal ring 130, the sensing devices 21 and the conductive towers 31 are formed within the insulation layer 160. The conductive towers 31 are configured to provide discharge paths for the sensing devices 21.

In some embodiments, the semiconductor device 10 over the substrate 100 is located on an inner side of a scribe line 103 (alternatively referred to as a dicing line or a cutting line). In a die sawing operation, the semiconductor device 10 is separated along the scribe line 103 by, e.g., laser cutting or blade cutting. The boundary of the semiconductor device 10 will be accordingly formed, and can be regarded as an outer border 122 of the substrate 100. Thus, the seal ring 130, the sensing devices 21 and the conductive towers 31 are disposed between the circuit region 11 and the outer border 122 of the substrate 100.

In some embodiments, the circuit region 11 of the substrate 100 includes a circuitry, such as a memory circuit, e.g., a dynamic random access memory (DRAM) circuit, a static random access memory (SRAM) circuit, a non-volatile memory circuit and/or another memory circuit, a mixed-signal circuit, a signal processing circuit, a logic circuit, an analog circuit, another circuit, and/or any combinations thereof. It should be noted that the circuit region 11 is merely illustrative, and the scope of the application is not limited thereto. In some embodiments, the circuit region 11 includes at least one circuitry segment, such as a logic circuit segment and a memory circuit segment. In some embodiments, the logic circuit segment and the memory circuit segment are electrically coupled with each other.

In some embodiments, the material of the substrate 100 may include polysilicon, silane (SiH₄), di-silane (Si₂H₆), dichlorosilane (SiCl₂H₄), silicon germanium, gallium arsenic, or other suitable semiconductor materials so as to function as a conductive material under certain conditions. In some embodiments, the substrate 100 further includes doped regions, such as a P-well, an N-well, and/or a doped active region such as a P+doped active region. In some embodiments, the substrate 100 may further include other features, such as a buried layer and/or an epitaxy layer. In addition, the substrate 100 may be a semiconductor on insulator such as silicon on insulator (SOI). In some embodiments, the substrate 100 may include a doped epitaxy layer, a gradient semiconductor layer, and/or a semiconductor layer overlying another semiconductor layer of a different type such as a silicon layer on a silicon germanium layer. In some embodiments, the substrate 100 may include a multilayer silicon structure or a multilayer compound semiconductor configuration. In some embodiments, the substrate 100 includes an interlayer dielectric (ILD) layer. The ILD layer may be a silicon oxide layer or a layer formed of any suitable interlayer dielectric material.

In some embodiments, the insulation layer 160 (FIG. 3B) formed over the substrate 100 is a dielectric stack that includes several dielectric layers disposed over the substrate 100, wherein the seal ring 130, the sensing devices 21 and the conductive towers 31 are formed within the dielectric layers. The dielectric layers for forming the insulation layer 160 are omitted for the simplicity and clarity of the drawings. In some embodiments, the insulation layer 160 includes one or more low-k dielectric materials. The dielectric constant (k value) of the low-k dielectric material of the insulation layer 160 may be lower than 3.0, or lower than about 2.5, and the dielectric material is therefore also referred to as an extreme low-k (ELK) dielectric material. Relatively low density, lack of mechanical strength and sensitivity to thermal stress make low-k dielectric material very prone to damage. Conventional mechanical wafer dicing and scribing techniques are known to cause cracks, delaminations, and another type of defects in the low-k dielectric materials, thus damaging the semiconductor device 10. The sensing devices 21 are disposed to determine whether the semiconductor device 10 has defects such as cracks and delaminations in the low-k dielectric layer.

In addition, the insulation layer 160 may include organic dielectric material such as organic silicate glass (OSG), porous methyl silsesquioxane (p-MSQ), hydrogen silsesquioxane (HSQ), a combination thereof, or any suitable organic low-k or extreme low-k dielectric material. In some embodiments, the material of the insulation layer 160 may include inorganic dielectric material such as carbon-doped silicon oxide, fluorine-doped silicate glass (FSG), a combination thereof, or any suitable inorganic low-k or extreme low-k dielectric material. In some embodiments, the insulation layer 160 may include another suitable dielectric material, such as silicon oxide or phosphosilicate glass (PSG). In some embodiments, the insulation layer 160 includes silicon oxide.

In some embodiments, the seal ring 130 is located between the outer border 122 of the substrate 100 and the sensing devices 21. In some embodiments, the seal ring 130 is formed of metal lines and connecting vias. In some embodiments, the material of the seal ring 130 may include copper, aluminum, aluminum copper, aluminum silicon copper, tungsten, titanium, tantalum, titanium nitride, tantalum nitride, nickel silicide, cobalt silicide, another suitable conductive material, or combinations thereof. The seal ring 130 is a tightly interconnected structure, which not only provides mechanical support and structural reinforcement to the semiconductor device 10, but also prevents moisture and/or mobile ionic contaminants from penetrating through edges of the semiconductor device 10.

In addition, the seal ring 130 may include several conductive rings surrounding the circuit region 11. In some embodiments, four conductive rings 131, 132, 133 and 134 are disposed over the substrate 100, as shown in FIG. 2. The conductive rings 131-134 may have the same or different ring widths. The conductive rings 131-134 may be separated from each other at an equal distance or different distances. It should be noted that four conductive rings 131-134 shown in FIG. 2 is merely illustrative, and the scope of the application is not limited thereto. In some embodiments, single, two or more conductive rings can be disposed around the circuit region 11.

In some embodiments, the sensing devices 21 formed over the substrate 100 are located on an inner side of the seal ring 130. For example, the sensing devices 21 may be disposed between the seal ring 130 and the circuit region 11. In some embodiments, the seal ring 130 is electrically isolated from the sensing devices 21. In some embodiments, the sensing devices 21 in the sensor region As are evenly distributed around the circuit region 11. In addition, in some embodiments, two probe pads (not shown) may be electrically connected to two ends of each of the sensing devices 21, and may be used to determine whether the semiconductor device 10 has defects.

In some embodiments, the extending direction of the sensing devices 21 is substantially in parallel with the extending direction of the seal ring 130, and separated from the seal ring 130 by a distance Ds (FIG. 2). In some embodiments, the distance Ds between the seal ring region 13 and the sensor region As can be referred to as a width of the capacitor region Ac. The distance Ds can be determined based on a variety of factors, including, for example, the size of the semiconductor device 10, design rules for the semiconductor device 10, variables relating to the wafer on which the semiconductor device 10 is manufactured, width between adjacent dies on the wafer, and other factors, as one skilled in the art will understand. The distance Ds between the seal ring 130 and each of the sensing devices 21 can be the same or different depending on the actual demand.

It is known that the sensing devices 21 are electrically floating during mechanical testing and production stages, and process-induced charges are accumulated in the sensing devices 21 before the sensing devices 21 are connected to protective circuits (e.g., Electrostatic discharge (ESD) protection circuit). Excessive charges accumulated in the sensing devices 21 may damage the sensing devices 21. According to the embodiments, capacitor structures are integrated with the sensing devices 21 for charge release. In some embodiments, formation of dummy metal towers as charging reservoirs, formation of MoM structures (metal-oxide-metal formed by dummy metals) or MiM structures (Metal-insulator-metal) in the semiconductor device 10 are described below to effectively solve the problem of charge accumulation in the sensing devices 21.

In some embodiments, an enlarged portion of the enhanced region 14 is depicted in FIG. 3A. A sensing device 21 is formed in the sensor region As, and several conductive towers 31 are formed in the capacitor region Ac. The sensing device 21 is in a chain configuration, and the details are described later.

In some embodiments, the sensing device 21 includes conductive stacks (such as metal stacks) that are arranged in the sensor region As in top view. In some embodiments, the conductive towers 31 arranged in the capacitor region Ac are electrically connected to the sensing device 21. In this exemplary embodiment, the topmost conductive layers (e.g., the top conductive layers 213) of the sensing device 21 are connected to the topmost conductive portions (e.g., the top conductive portions 313) of the conductive towers 31.

In some embodiments, at least some of dummy metal islands that are originally formed between the seal ring region 13 and the seal ring sensor region As for providing mechanical support and pattern uniformity can be utilized to form the conductive towers 31. In some embodiments, the topmost conductive layers (e.g., the top conductive layers 213) of the sensing device 21 extend to reach these dummy metal islands, thereby forming the conductive towers 31 connected to the sensing device 21, in accordance with some embodiments. Use of original dummy metal islands to form capacitors that are connected to the floating sensors (i.e., the sensing device 21) does not occupy extra chip area.

In some embodiments, each of the sensing device 21 is in a chain configuration. As shown in FIG. 3B, the sensing device 21 is a daisy chain. In some embodiments, each of the sensing devices 21 includes several connection structures 212, several top conductive layers 213 and several bottom conductive layers 211. The top conductive layers 213 and the bottom conductive layers 211 are alternately arranged between the connection structures 212. In some embodiments, the bottom conductive layers 211 are disposed over the substrate 100, and the top conductive layers 213 are disposed over the connection structures 212. In some embodiments, each of the connection structures 212 is located between one of the top conductive layers 213 and one of the bottom conductive layers 211. In some embodiments, the connection structures 212 are serially connected by the top conductive layers 213 and the bottom conductive layers 211.

In some embodiments, several interconnection structures are formed in the peripheral region 12 to construct the seal ring 130, the sensing devices 21 and the conductive towers 31. The interconnection structures may include metallization layer stacked vertically over the substrate 100 and conductive vias connecting the metallization layers. In some embodiments, as shown in FIG. 3B, the bottom conductive layers 211 of the sensing device 21 are distributed in a bottom metallization layer M0 of an interconnection structure, and the top conductive layers 213 are distributed in a top metallization layer MT of the interconnection structure. In some embodiments, two adjacent connection structures 212 are electrically connected by the top conductive layer 213 or the bottom conductive layer 211, alternatively. In some embodiments, two ends of each bottom conductive layer 211 are electrically connected to the two adjacent connection structures 212.

In some embodiments, each of the conductive towers 31 comprises a bottom conductive portions 311, a connection structure 312 and a top conductive portion 313 that are sequentially formed over the substrate 100. In some embodiments, as shown in FIG. 3B, the top conductive layers 213 of the sensing device 21 extend to connect the top conductive portions 313 of the conductive towers 31. In some embodiments, the top metallization layer MT can be patterned to form continuous sections. As shown in FIG. 3A, two continuous sections of the top metallization layer MT in top view may be formed in a mirror symmetry fashion. Each of the continuous sections includes two L-shaped top metal portions connected to each other in top view. In some embodiments, as shown in FIG. 3A, a part of the continuous section of the top metallization layer MT serve as the top conductive layer 213 of the sensing device 21, and some parts of the continuous section of the top metallization layer MT serve as the top conductive portions 313 of the conductive towers 31. Remaining parts of the continuous section serve as linking portions connecting adjacent conductive towers 31 and adjacent conductive tower 31 and the sensing device 21. In some embodiments, the conductive towers 31 can also be referred to as metal towers 31.

It should be noted that the bottommost conductive layers (i.e., the bottom conductive portions 311) of the conductive towers 31 are at a horizontal level higher than the bottommost conductive layers (i.e., the bottom conductive layers 211) of the sensing device 21, in accordance with some embodiments. In some embodiments, the bottom conductive portion 311 of the conductive tower 31 is vertically separated from the underlying bottom conductive layer 211 of the sensing device 21 by a distance Db.

In some embodiments, as shown in FIG. 3A and FIG. 3B, the conductive towers 31 are formed as charging reservoirs. The conductive towers 31 may be referred to as capacitive conductive stacks. When the sensing devices 21 are electrically floating during mechanical testing or production, prior to their connection with protective circuits, the process-induced charges in the floating sensing devices 21 can be released to the conductive towers 31. Accordingly, the semiconductor device 10 provided in some embodiments effectively prevents excessive charges from flowing into the sensing devices 21 and burning the bottoms of the sensing devices. Thus, the EOS risk that often occurred in the conventional seal ring sensors can be greatly reduced.

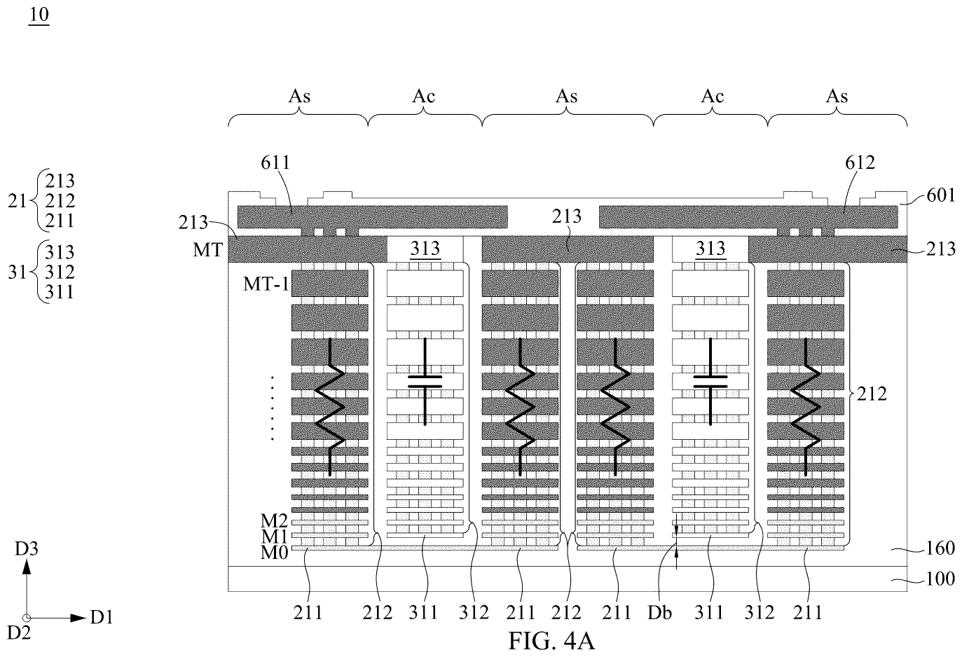

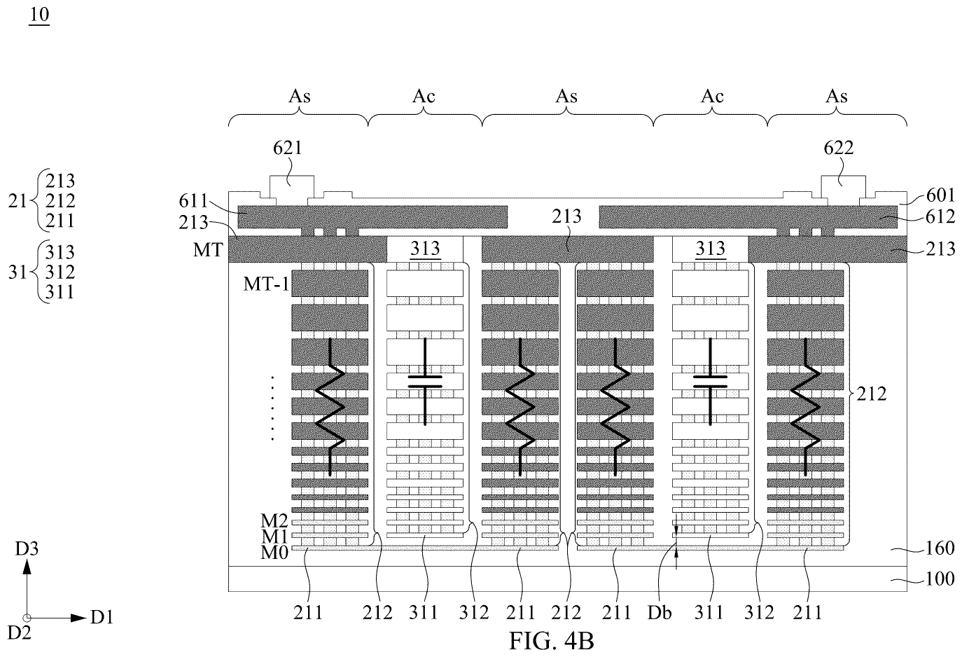

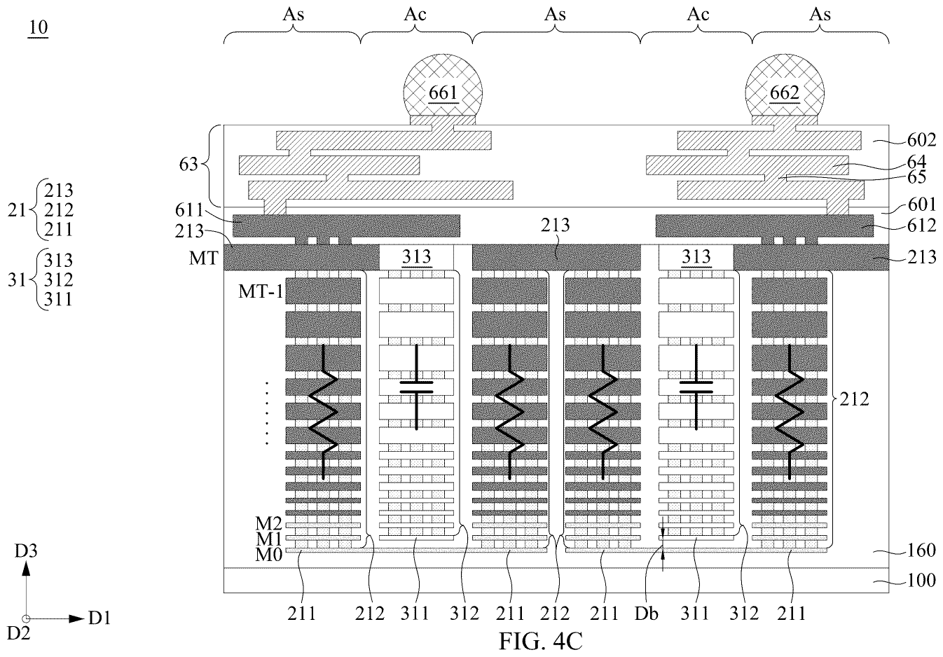

FIG. 4A is a schematic cross-sectional view of a semiconductor device in accordance with some embodiments of the present disclosure. In some embodiments, a first probe pad 611 and a second probe pad 612 are configured to transfer a test signal from a testing apparatus to each of the sensing devices 21. The first probe pad 611 and the second probe pad 612 are connected to two different top conductive layers 213 at the two ends of each sensing device 21. In some embodiments, the first probe pad 611 and the second probe pad 612 are positioned above the sensing devices 21, and are connected to the top conductive layers 213 by the vias 6171 and 6172, respectively.

In some embodiments, a passivation layer (including one or more passivation films) 601 is formed over the sensing devices 21, the conductive towers 31 and the insulation layer 160. The first probe pad 611 and the second probe pad 612 are exposed through the openings in the passivation layer 601. In some embodiments, the shape of each of the first probe pad 611 and the second probe pad 612 from the top view is not particularly limited, and may be adjusted according to the actual needs. In some embodiments, the passivation layer 601 may be a polyimide, a borophosphosilicate glass (BPSG), silicon nitride (SiN), polybenzoxazole (PBO), a combination thereof, and/or the like, and may be formed using a spin-on technique, CVD, ALD, PVD, and/or a combination thereof.

In addition, according to some embodiments, the conductive towers 31 in the capacitor region Ac that provide discharge paths to prevent excessive charges from flowing into the sensing devices 21 and EOS (i.e., electrical over stress) damage to the bottoms of the sensing devices 21. Occurrence of EOS induces an unwanted open signal and introduces false judgment of mechanical damage. That is, by applying a test signal to the first probe pad 611 and sensing the test signal at the second probe pad 612 of the sensing devices 21 under test, the test result can be used to determine whether the sensing devices 21 itself under test has a defect (such as a void or discontinuity). That is, according to the test signal, the continuity profile of the sensing devices 21 under test can be accurately determined.

FIG. 4B is a schematic cross-sectional view of a semiconductor device in accordance with some embodiments of the present disclosure. In some embodiments, the semiconductor device further includes a first bump 621 and a second bump 622 disposed on the first probe pad 611 and the second probe pad 612, respectively. The first bump 621 and the second bump 622 are exposed through the openings in the passivation layer 601. Thus, the first probe pad 611 and the second probe pad 612 can be probed through the first bump 621 and the second bump 622. The first bump 621 and the second bump 622 are electrically connected to (e.g., in direct contact with) the first probe pad 611 and the second probe pad 612, respectively.

In addition, according to some embodiments, the conductive towers 31 in the capacitor region Ac prevent EOS damage to the bottoms of the sensing devices 21. By applying a test signal to the first bump 621 (coupled to the first probe pad 611) and sensing the test signal at the second bump 622 (coupled to the probe pad 612), the test result can be used to determine whether the sensing devices 21 themselves under test have defects (such as a void or discontinuity). That is, according to the test signal, the continuity profile of the sensing devices 21 can be accurately determined.

In some embodiments, the first bump 621 and the second bump 622 are conductive balls. In some embodiments, the first probe pad 611 and the second probe pad 612 may include copper, tin, eutectic solder, lead free solder, nickel, and combinations thereof, and may be formed by electrochemical plating (ECP) and/or another suitable process. In some embodiments, the first bump 621 and the second bump 622 are added to the semiconductor device after the semiconductor device is singulated.

FIG. 4C is a schematic cross-sectional view of a semiconductor device in accordance with some embodiments of the present disclosure. In some embodiments, the semiconductor device further includes a redistribution layer 63, a first conductor 661 and a second conductor 662 formed on the redistribution structure 63. In some embodiments, the redistribution structure 63 includes metallization layers 64 and vias 65 formed in an inter-metal dielectric (IMD) layer 602. In some embodiments, the first conductor 661 is electrically connected to the first probe pad 611, and the second conductor 662 is electrically connected to the second probe pad 612. In some embodiments, the first probe pad 611 and the second probe pad 612 can be probed to determine a connection status of the sensing device 21 through the first conductor 661, the second conductor 662, the metallization layers 64 and the vias 65. In some embodiments, the first conductor 661 and the second conductor 662 are added to the semiconductor device after the semiconductor device is singulated.

In addition, according to some embodiments, the conductive towers 31 in the capacitor region Ac prevent EOS damage to the bottoms of the sensing devices 21. By applying a test signal to the first conductor 661 (coupled to the first probe pad 611) and sensing the test signal at the second conductor 662 (coupled to the second probe pad 612), the test result can be used to determine whether the sensing devices 21 themselves under test have defects (such as a void or discontinuity). That is, according to the test signal, the continuity profile of the sensing devices 21 can be accurately determined.

In some embodiments, the semiconductor device in FIG. 4C can be used in the assembly stage to determine a connection status of a package. In addition, in some embodiments, the IMD layers 602 may include an oxide dielectric, such as a borophosphosilicate glass (BPSG), or another dielectric material. In some embodiments, the conductive material of the metallization layers 64 may be, for example, copper, nickel, aluminum, copper aluminum, tungsten, titanium, combinations thereof, and/or the like.

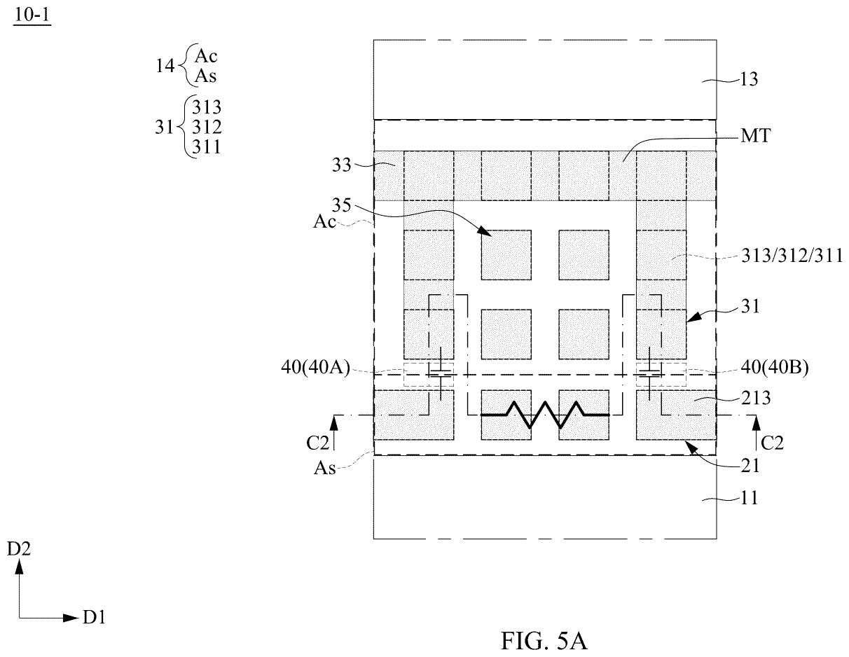

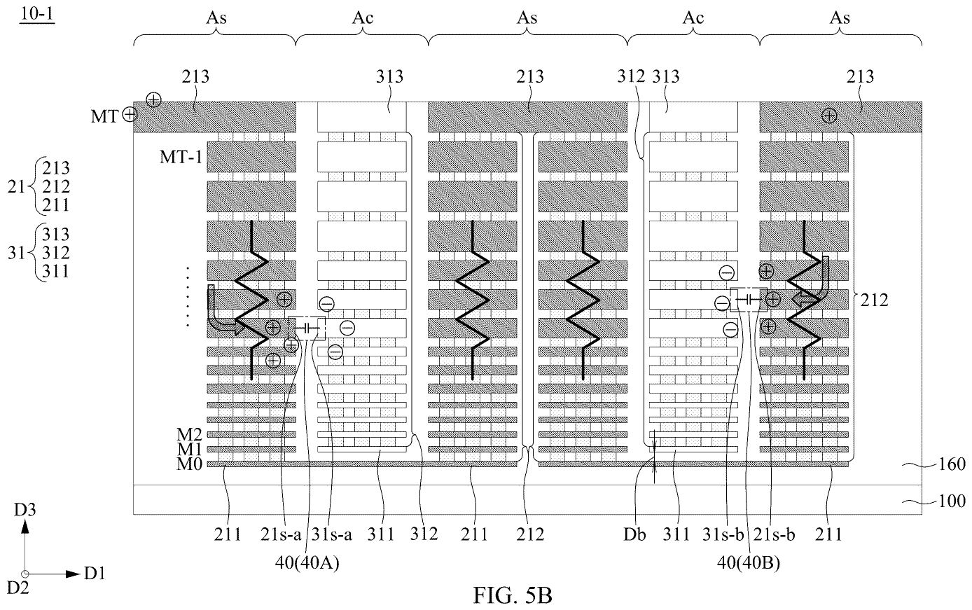

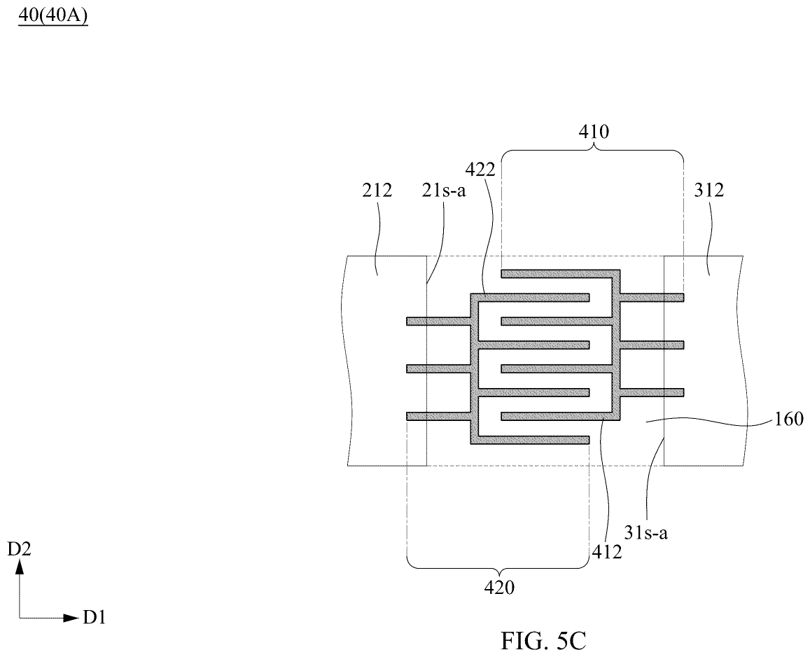

FIG. 5A is a schematic top view of the semiconductor device in the enhanced region 14 of FIG. 2. FIG. 5B is a schematic cross-sectional view of the semiconductor device taken along line C2-C2 in FIG. 5A. The features/components in FIG. 5A and FIG. 5B similar or identical to the features/components in FIG. 3A and FIG. 3B are designated with similar or the same reference numbers, and the details of those similar or the identical features/components are not repeated herein. Details of the arrangement, materials and manufacturing methods of the components shown in FIG. 5A and FIG. 5B are essentially the same as what have been discussed referring to FIG. 3A and FIG. 3B, and are not repeated herein.

Referring to FIG. 1, FIG. 2, FIG. 5A and FIG. 5B, in some embodiments, the semiconductor device 10-1 includes a substrate 100, a seal ring 130 formed in the seal ring region 13, the sensing devices 21 and the conductive towers 31 formed in the enhanced region 14. The semiconductor device 10-1 further includes an insulation layer 160 formed over the substrate 100. The seal ring 130, the sensing devices 21 and the conductive towers 31 are formed within the insulation layer 160.

The difference between the semiconductor device 10-1 in FIG. 5B and the semiconductor device 10 in FIG. 3B is the configuration of discharging paths. In some embodiments, the semiconductor device 10-1 includes capacitor structures 40 each having a metal-oxide-metal (MoM) structure to store process-induced charges, thereby effectively preventing excessive electrical charges from damage to the sensing devices 21.

In some embodiments, as shown in FIG. 5A, each of the sensing devices 21 includes conductive stacks (such as metal stacks) that are arranged in the sensor region As in top view. In some embodiments, the conductive towers 31 that are arranged in the capacitor region Ac are electrically isolated from the sensing device 21. In some embodiments, the semiconductor device 10-1 further includes capacitor structures 40, and each of the capacitor structures 40 is formed between one of the conductive towers 31 and the sensing device 21 proximate to the conductive tower 31. The conductive towers 31 may also be referred to as capacitive conductive stacks. In some embodiments, the capacitor structures 40 are embedded in the insulation layer 160.

In some embodiments, as shown in FIG. 5A, a capacitor structure 40A is formed between a current flow-in conductive stack of the sensing device 21 and adjacent conductive tower 31. Specifically, as shown in FIG. 5B, a capacitor structure 40A is formed between a side surface 31s-a of a metallization layer of the conductive tower 31 and the side surface 21s-a of the proximate conductive stack of the sensing device 21.

In some embodiments, as shown in FIG. 5A, another capacitor structure 40B is formed between a current flow-out conductive stack of the sensing device 21 and adjacent conductive tower 31. Specifically, as shown in FIG. 5B, the capacitor structure 40B is formed between the side surface 31s-b of a metallization layer of the conductive tower 31 and a side surface 21s-b of the proximate conductive stack of the sensing device 21.

In some embodiments, the capacitor structures 40A and 40B can be formed by using different metallization layers. That is, the capacitor structures 40A and 40B may be constructed in different horizontal levels. In some embodiments, the capacitor structures 40A and 40B can be formed by using one of the metallization layers. That is, the capacitor structures 40A and 40B may be constructed in the same horizontal level.

FIG. 5C is an enlarged top view of a capacitor structure in FIG. 5A. In some embodiments, each of the capacitor structures 40, such as the capacitor structure 40A or the capacitor structure 40B, is an electrode structure that has a comb-shaped positive electrode and a comb-shaped negative electrode.

In some embodiments, the capacitor structure 40A includes a first electrode 410 and a second electrode 420. The first electrode 410 extends from the side surface 31s-a of the conductive tower 31, and the second electrode 420 extends from the side surface 21s-a of the sensing device 21 that is proximate to the side surface 31s-a of the conductive tower 31. In some embodiments, the first electrode 410 includes several first finger segments 412, and the second electrode 420 includes several second finger segments 422 that extend towards the first finger segments. In some embodiments, the first finger segments 412 and the second finger segments 422 are alternately arranged at equal distances. In some embodiments, the first electrode 410 and the second electrode 420 of each of the capacitor structures 40 are formed in the same horizontal plane.

In some embodiments, since the capacitor structures 40 are embedded in the insulation layer 160, they can be also referred to as metal-oxide-metal (MoM) capacitors when the insulation layer 160 includes an oxide material (such as silicon oxide) as the dielectric medium between the first electrode 410 and the second electrode 420.

In addition, as shown in FIG. 5B, the capacitor structures 40 may be formed at the middle levels or lower levels of the metal stacks of the sensing device 21 and the conductive towers 31 to store electrical charges from the floating sensing device 21. Specifically, in some embodiments, the first electrode 410 of each of the capacitor structures 40 can be fabricated by a conductive layer of a middle portion or a lower portion of the connection structures 312 of the conductive tower 31. In some embodiments, the second electrode 420 of each of the capacitor structures 40 can be fabricated by a conductive layer of a middle portion or a lower portion of the connection structures 212 of the sensing device 21.

According to some embodiments, the conductive towers 31 are configured to provide discharge paths for the sensing devices 21, thereby releasing excessive charges accumulated in the sensing devices 21. According to the capacitor structures 40, such as capacitor structures 40A and 40B, which are formed between the conductive towers 31 and adjacent metal stacks of the sensing device 21, the excessive charges in the floating sensing devices 21 can be stored in the capacitor structures 40, thereby improving the reliability and functionality of the sensing devices 21.

In addition, the conductive towers 31 can be coupled to a ground terminal (e.g., ground terminal Vss), in accordance with some embodiments of the present disclosure. In some embodiments, a common conductive line 33 is connected to the top conductive portions 313 of the capacitive conductive towers 31, and the common conductive line 33 is coupled to a ground terminal to release the charges. The common conductive line 33 may continuously extend to connect all of the capacitive conductive towers 31 around the circuit region 11 and then is coupled to a ground terminal.

In some embodiments, the common conductive line 33 may be arranged in parallel with the extending direction of the sensing devices 21. In some embodiments, the semiconductor device 10-1 may further include several dummy stacks 35 that are disposed adjacent to the capacitive conductive towers 31 and the sensing devices 21. As shown in FIG. 5A, the dummy stacks 35 are disposed in the region between the common conductive line 33, the capacitive conductive towers 31 and the sensing device 21. The dummy stacks 35 provide mechanical support and pattern uniformity at the regions for disposing the sensing devices and the conductive towers.

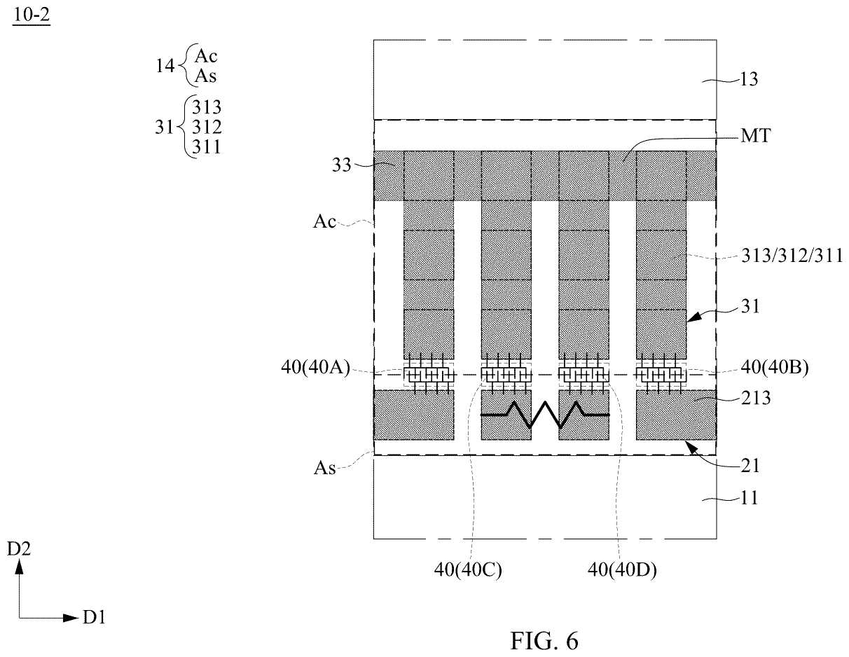

FIG. 6 is a schematic top view of the semiconductor device in the enhanced region 14 of FIG. 2. The difference between the semiconductor device 10-1 in FIG. 5A and the semiconductor device 10-2 in FIG. 6 is that the dummy stacks 35 in FIG. 5A are further utilized to form other capacitive conductive towers 31 in FIG. 6. That is, the semiconductor device 10-2 in FIG. 6 may be similar to the semiconductor device 10-1 in FIG. 5A described previously, except no dummy stack is formed independently at the capacitor region Ac in FIG. 6.

In some embodiments, the semiconductor device 10-2 includes the capacitor structures 40A, 40B, 40C and 40D between each of the conductive stacks of the sensing device 21 and adjacent conductive towers 31. Structural details of the capacitor structures 40C and 40D may be substantially the same as what have been discussed referring to FIG. 3A and FIG. 3B, and are not repeated herein.

In addition, in some embodiments, as shown in FIG. 6, those capacitive conductive towers 31 are connected to the common conductive line 33 through a continuous pattern of a top conductive portion 313 that is formed over the connection structures 312 of the conductive towers 31. In some embodiments, the common conductive line 33 is coupled to a ground terminal. According to some embodiments, the top view pattern formed by the combination of conductive towers 31 and sensing device 21 is not limited to the schematic patterns shown in FIG. 5B and FIG. 6. Another top view pattern of the combination of conductive towers 31 and sensing device 21 may be formed to implement MoM capacitors as described above.

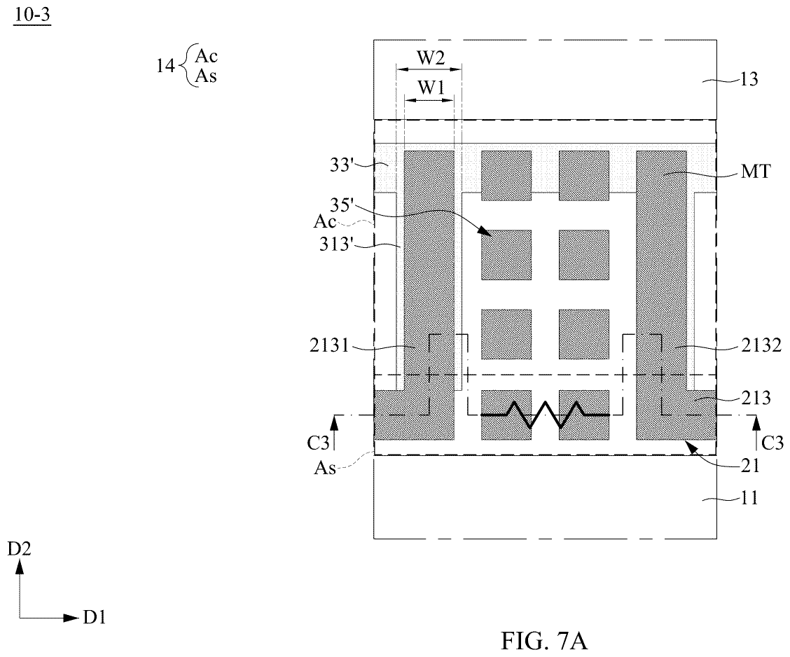

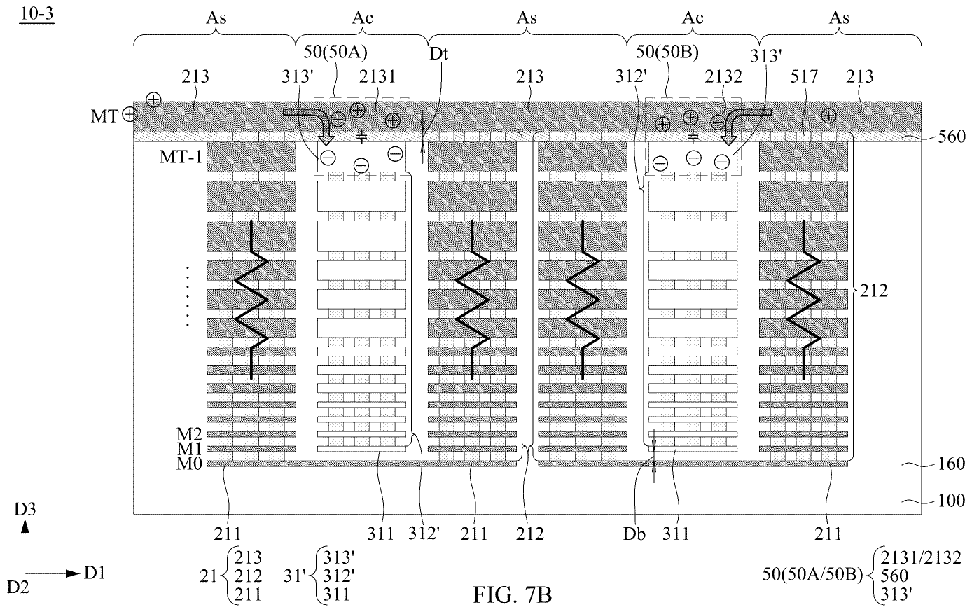

FIG. 7A is a schematic top view of the semiconductor device in the enhanced region 14 of FIG. 2. FIG. 7B is a schematic cross-sectional view of the semiconductor device taken along line C3-C3 in FIG. 7A. The features/components in FIG. 7A and FIG. 7B similar or identical to the features/components in FIG. 3A and FIG. 3B are designated with similar or the same reference numbers, and the details of those similar or the identical features/components are not repeated herein. Details of the arrangement, materials and manufacturing methods of the components shown in FIG. 7A and FIG. 7B are similar to or essentially the same as what have been discussed referring to FIG. 3A and FIG. 3B, and are not repeated herein.

Referring to FIG. 1, FIG. 2, FIG. 7A and FIG. 7B, in some embodiments, the semiconductor device 10-3 includes a substrate 100, a seal ring 130 formed in the seal ring region 13, the sensing devices 21 and the conductive towers 31′ formed in the enhanced region 14. The semiconductor device 10-3 further includes an insulation layer 160 formed over the substrate 100, and a dielectric layer 560 formed on the insulation layer 160.

In some embodiments, the conductive towers 31′ and the connection structures 212 of the sensing devices 21 are formed within the insulation layer 160. In some embodiments, the top conductive layers 213 of the sensing devices 21 and the vias 517 that connect the top conductive layers 213 to the connection structures 212 of the sensing devices 21 or the top conductive portions 313′ of the conductive towers 31′ are formed in the dielectric layer 560. Specifically, in some embodiments, the dielectric layer 560 is formed on the topmost conductive portions 313′ of the conductive towers 31′, and the top conductive layers 213 of the sensing device 21 are formed on the dielectric layer 560. In some embodiments, the dielectric constant (k) of the dielectric layer 560 is greater than the dielectric constant of the insulation layer 160.

The difference between the semiconductor device 10 in FIG. 5B and the semiconductor device 10-3 in FIG. 7B is the configuration of discharging paths. As described above, the semiconductor device 10-1 in FIG. 5B includes capacitor structures 40 each having a metal-oxide-metal (MoM) structure to store process-induced charges. In this exemplified embodiment, the semiconductor device 10-3 in FIG. 7B includes capacitor structures 50 each having a metal-insulator-metal (MiM) structure to store process-induced charges, thereby effectively preventing excessive electrical charges from damage to the sensing devices 21. In some embodiments, the capacitor structures 50 are formed on the top of each of the conductive towers 31′. Thus, the conductive towers 31′ can also be referred to as capacitive conductive stacks.

In some embodiments, the dielectric layer 560 includes a high-k dielectric material, and the insulation layer 160 includes a low-k dielectric material. In some embodiments, the dielectric layer 560 may include a nitride layer, a silicon nitride layer, or other dielectric material layers of high dielectric constant. In some embodiments, the dielectric layer 560 is a silicon nitride layer deposited by low-temperature CVD or plasma-enhanced CVD (PECVD) methods. In some embodiments, the dielectric layer 560 is a silicon nitride layer of a thickness of about 250 Angstroms or less formed by a PECVD method at a process temperature less than about 200 degree Celsius, thereby achieving an enhanced capacitance density in the MiM capacitors.

In some embodiments, as shown in FIG. 7A, each of the sensing devices 21 includes conductive stacks (such as metal stacks) that are substantially arranged in the sensor region As in top view. In some embodiments, each of the sensing devices 21 includes metal stacks disposed over the substrate 100 and at least one arm portion connected to one of the metal stacks. In this illustrative example, the top conductive layer 213 of the sensing device 21 includes two arm portions 2131 and 2132 that extend above the top conductive portions 313′ of the conductive towers 31′.

In addition, in some embodiments, the top conductive portions 313′ of the conductive towers 31′ are connected to a common conductive line 33′. In some embodiments, the common conductive line 33′ is coupled to a ground terminal to release the charges. The common conductive line 33′ may continuously extend to connect all of the capacitive conductive towers 31′ around the circuit region 11, and then is connected to a ground terminal.

In some embodiments, as shown in FIG. 7B, each of the conductive towers 31′ includes a bottom conductive portion 311, a connection structure 312′ and a top conductive portion 313′. In some embodiments, the top conductive portions 313′ of the conductive towers 31′ are lower than the top conductive layers 213 of the sensing devices 21. In some embodiments, each of the top conductive portions 313′ of the conductive towers 31′ are vertically separated from the arm portions 2131 and 2132 of the top conductive layers 213 of the sensing device 21 by a distance Dt. In some embodiments, the arm portions 2131 and 2132 of the top conductive layer 213 of the sensing device 21 protrude toward the common conductive line 33′ that is connected to the top conductive portions 313′ of the conductive towers 31′.

In some embodiments, the arm portion 2131 of the top conductive layer 213, the top conductive portion 313′ under the arm portion 2131, and the high-k dielectric material of the dielectric layer 560 between the arm portion 2131 and the top conductive portion 313′ form a capacitor structures 50A (e.g., MiM capacitor). Similarly, in some embodiments, the arm portion 2132 of the top conductive layer 213, the top conductive portion 313′ under the arm portion 2132, and the high-k dielectric material of the dielectric layer 560 between the arm portion 2132 and the top conductive portion 313′ form a capacitor structures 50B (e.g., MiM capacitor).

It is known that capacitance is directly proportional to overlap area between the upper and lower electrodes. In some embodiments, the top conductive portion 313′ (e.g., referred to as a lower electrode of the capacitor structure 50) may be wider than, equal to or narrow than the arm portion of the top conductive layer 213 (e.g., referred to as an upper electrode of the capacitor structure 50). For example, the arm portion 2131 of the top conductive layer 213 has a width W1, the top conductive portion 313′ under the arm portion 2131 has a width W2, and the width W1 may be greater than the width W2, as shown in FIG. 7A. Alternatively, the width W1 may be substantially the same as or less than the width W2. In some embodiments, the pattern and width of the top conductive portion 313′ are similar or substantially coincident with that of the arm portion of the top conductive layer 213. The larger the overlapping area between the top conductive portion 313′ and the arm portions 2131 and 2132, the greater the capacitance.

In addition, in some embodiments, the semiconductor device 10-3 further includes several dummy stacks 35′ that are disposed adjacent to the capacitive conductive towers 31′ and the sensing devices 21. The dummy stacks 35′ provide mechanical support and pattern uniformity at the regions for disposing the sensing devices 21 and the conductive towers 31′.

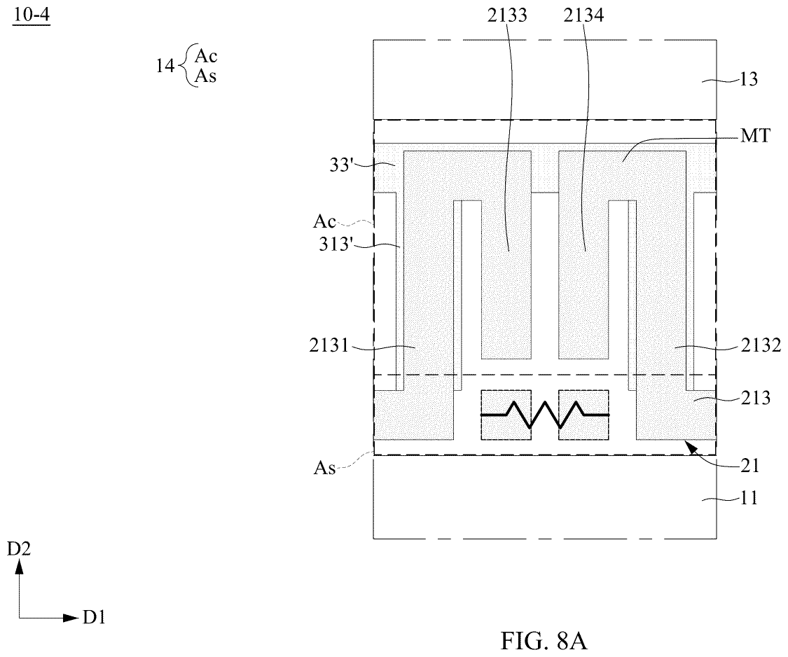

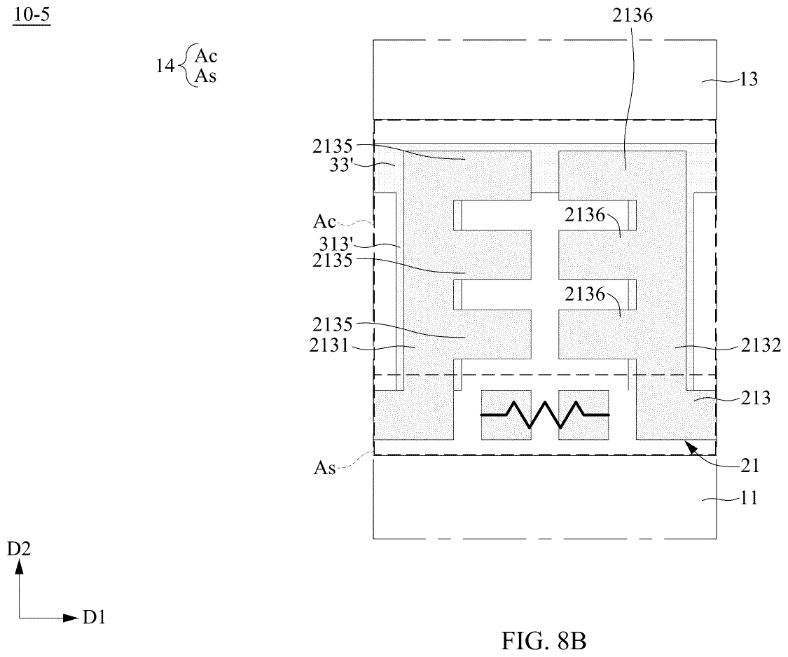

FIG. 8A is a schematic top view of the semiconductor device in the enhanced region 14 of FIG. 2. The difference between the semiconductor device 10-3 in FIG. 7A and the semiconductor device 10-4 in FIG. 8A is that the dummy stacks 35′ in FIG. 7A are further grouped and connected to the arm portions 2131 and 2132 of the top conductive layer 213. More specifically, as shown in FIG. 8A, the semiconductor device 10-4 further includes L-shape arm portions 2133 and 2134 in top view. In some embodiments, the arm portion 2133 is connected to the arm portion 2131, and the arm portion 2134 is connected to the arm portion 2132.

FIG. 8B is a schematic top view of the semiconductor device in the enhanced region 14 of FIG. 2. The difference between the semiconductor device 10-3 in FIG. 7A and the semiconductor device 10-5 in FIG. 8B is that the dummy stacks 35′ in FIG. 7A are further grouped and connected to the arm portions 2131 and 2132 of the top conductive layer 213. The difference between the semiconductor device 10-4 in FIG. 8A and the semiconductor device 10-5 in FIG. 8B is the pattern of the top conductive layer 213. More specifically, as shown in FIG. 8B, the semiconductor device 10-5 further includes several arm portions 2135 connected to the arm portion 2131 and several arm portions 2136 connected to the arm portion 2132. In some embodiments, the arm portions 2135 are substantially perpendicular to the arm portion 2131, and the arm portions 2136 are substantially perpendicular to the arm portion 2132.

It should be noted that the top conductive layer 213 and the top conductive portion 313′ may have different patterns in top view to form capacitors on the conductive towers 31′m and they are not limited to the patterns in FIG. 6, FIG. 8A and FIG. 8B.

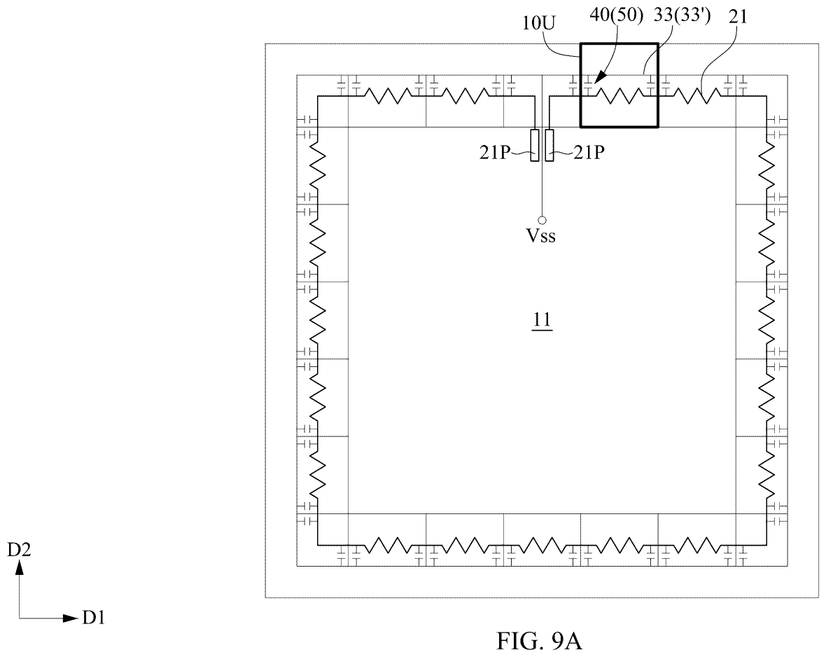

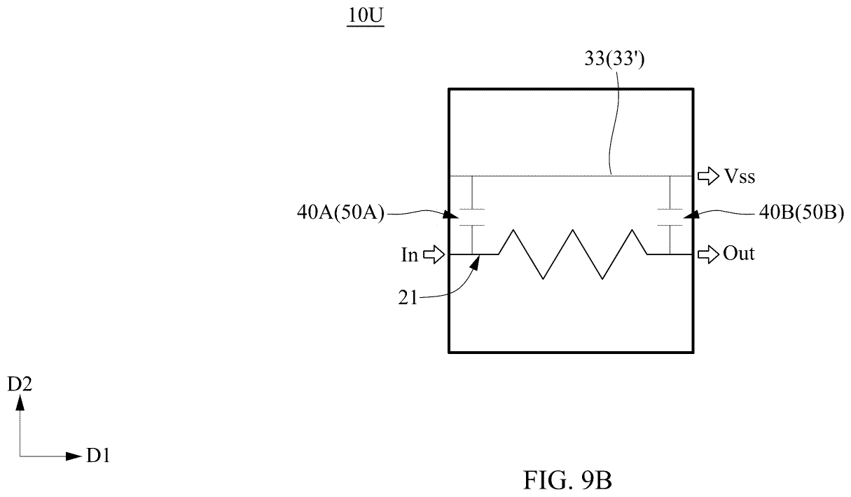

FIG. 9A shows equivalent circuits of the sensing devices and the capacitors surrounding the outside of the circuit region 11, in accordance with some embodiments of the present disclosure. As shown in FIG. 9A, several sensing devices 21 are serially connected to form a crack sensor that has a conductive path between two electrically connected probe pads 21P. The capacitors, such as the above-mentioned capacitor structures 40 in FIGS. 5A, 5B and 5 or capacitor structures 50 in FIGS. 7A, 7B, 8A and 8B, may be integrated with the sensing devices 21. In some embodiments, those capacitors may be coupled to a ground terminal Vss through a common conductive line.

FIG. 9B shows equivalent circuits in one of the repeating units 10U of FIG. 9A. In some embodiments, there are several repeating units 10U serially arranged at the outside of the circuit region 11. As shown in FIG. 9B, each of the repeating units 10U includes a sensing device 21 and two capacitors. As described in the aforementioned embodiments shown in FIGS. 5A, 5B, 7A and 7B, the two capacitors may be integrated with a current flow-in conductive stack and a current flow-out conductive stack of the sensing device 21.

After a seal ring 130, a crack sensor (e.g., a chain of the sensing devices 21) and the capacitors (e.g., capacitor structures 40 and/or capacitor structures 50) are formed, the crack sensor forms a close loop daisy chain surrounding the circuit region 11 to monitor mechanical damages, while the capacitors are disposed in parallel with the crack sensor, in accordance with some embodiments of the present disclosure.

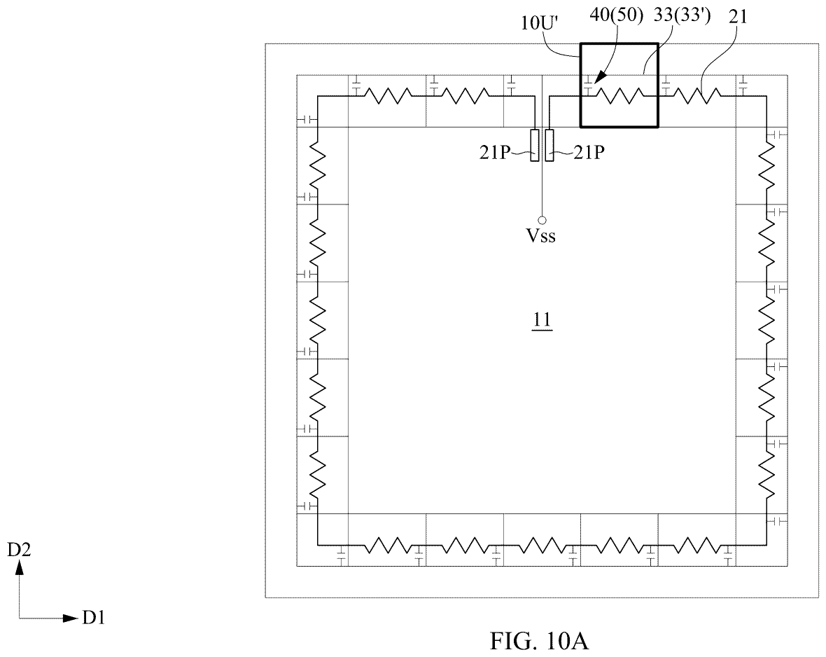

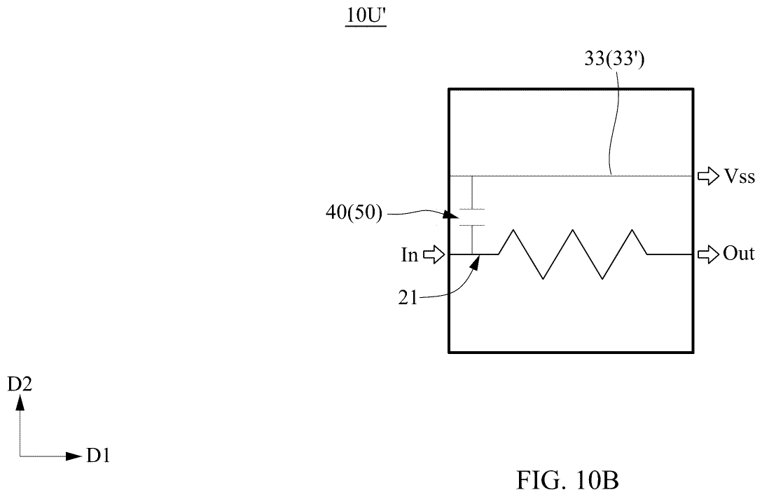

FIG. 10A shows equivalent circuits of the sensing devices and the capacitors surrounding the outside of the circuit region, in accordance with some embodiments of the present disclosure. FIG. 10B shows equivalent circuits in one of the repeating units 10U′ of FIG. 10A. The features/components in FIG. 10A and FIG. 10B similar or identical to the features/components in FIG. 9A and FIG. 9B are designated with similar or the same reference numbers, and the details of those similar or the identical features/components are not repeated herein. In FIG. 10A and FIG. 10B, each of the repeating units 10U′ includes a sensing device 21 and a capacitor. In some embodiments, the capacitor (e.g., the capacitor structure 40 or the capacitor structures 50) can be integrated at one end of the sensing device 21. For example, the capacitor is integrated with one of the current flow-in conductive stack and the current flow-out conductive stack of the sensing device 21.

In addition, simulator model circuits (e.g., extracted by SPICE model) also prove that EOS burn-out can be presented by integrating capacitor with the sensing devices (i.e. the seal ring sensor). During simulation, a crack sensor of some embodiments is modeled as resistor with additional capacitors. Process-induced charges is modeled as voltage source switch. Switch is turned-on to simulate excessive charge pumped into the crack sensor. In some but not limited simulations, without capacitor (capacitance value less than 1 pF), the resistor's power is high (about 4 W). On the other hand, with capacitor (capacitance value about 1 uF), the resistor's power is reduced to approximately 17% (about 0.69 W) or lower. That is, the capacitors integrated with the sensing devices, in accordance with some embodiments of the present disclosure does reduce the power of the crack sensor and suppress the burn-out defects.

According to the embodiments, a semiconductor device that includes sensing devices and conductive towers is provided. The conductive towers that are configured in the form of capacitors that provide discharge paths for the sensing devices. The charges (such as process-induced charges) that are accumulated in the floating sensing devices can be released through the discharge paths. Thus, the semiconductor device of the embodiments prevents excessive charges from damaging the sensing devices, and the reliability and functionality of the sensing devices can be improved. Thus, the EOS risk that often occurred in the conventional seal ring sensors can be greatly reduced. In addition, in some embodiments, use of original dummy metal islands to form conductive towers that are connected to the floating sensing device 21 or configured to form capacitors with the sensing device 21 does not occupy extra chip area. In addition, the semiconductor device and a method for forming the semiconductor device, in accordance with some embodiments of the present disclosure, effectively prevent the sensing devices from being burned out, thereby improving production yield and reducing wastes during production. Thus, the semiconductor device of the embodiments and method for forming the same are devoted to green technology.

Some embodiments of the present disclosure provide a semiconductor device. The semiconductor device includes a substrate, a seal ring, sensing devices, conductive towers, and an insulation layer. The substrate has a circuit region and a peripheral region around the circuit region. The seal ring is formed over the substrate and disposed in the peripheral region. The sensing devices are formed over the substrate and disposed between the seal ring and the circuit region. The conductive towers are formed over the substrate and disposed between the seal ring and the sensing devices. The conductive towers are configured to provide discharge paths for the sensing devices. The insulation layer is formed over the substrate. The seal ring, the sensing devices and the conductive towers are formed within the insulation layer.

Some embodiments of the present disclosure provide a semiconductor device. The semiconductor device includes a substrate, a seal ring, sensing devices, capacitive metal towers, and an insulation layer. The substrate includes a circuit region and an outer border. The seal ring is formed over the substrate and disposed between the outer border of the substrate and the circuit region. The sensing devices are formed over the substrate and disposed between the seal ring and the circuit region. The capacitive metal towers are formed over the substrate and positioned proximate to the sensing devices. The capacitive metal towers are configured to provide discharge paths for the sensing devices. The insulation layer is formed over the substrate. The seal ring, the sensing devices, and the capacitive metal towers are formed within the insulation layer.

Some embodiments of the present disclosure provide a method for forming a semiconductor device. The method includes following operations: providing a substrate having a circuit region and a peripheral region around the circuit region; forming interconnection structures in the peripheral region; and forming an insulation layer over the substrate. The interconnection structures include a seal ring, sensing devices and conductive towers formed over the substrate. The sensing devices are disposed between the seal ring and the circuit region. The conductive towers are formed between the seal ring and the sensing devices. The conductive towers are configured to provide discharge paths for the sensing devices. The seal ring, the sensing devices and the conductive towers are formed in the insulation layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate having a circuit region and a peripheral region around the circuit region;
a seal ring formed over the substrate and disposed in the peripheral region;
sensing devices formed over the substrate and disposed between the seal ring and the circuit region;
conductive towers formed over the substrate and disposed between the seal ring and the sensing devices, wherein the conductive towers are configured to provide discharge paths for the sensing devices; and
an insulation layer formed over the substrate, wherein the seal ring, the sensing devices and the conductive towers are formed within the insulation layer.

2. The semiconductor device of claim 1, wherein the conductive towers are capacitive conductive stacks.

3. The semiconductor device of claim 1, wherein the conductive towers are connected to the sensing devices.

4. The semiconductor device of claim 1, wherein the conductive towers are coupled to a ground terminal.

5. The semiconductor device of claim 1, wherein a capacitor structure is formed between a side surface of one of the conductive towers and a side surface of the sensing device proximate to the one of the conductive towers.

6. The semiconductor device of claim 5, wherein the capacitor structure comprises:
a first electrode having first finger segments that extend from the side surface of the conductive tower; and
a second electrode having second finger segments that extend from the side surface of the sensing device and extend towards the first finger segments, wherein the first finger segments and the second finger segments are alternately arranged at equal distances.

7. The semiconductor device of claim 1, wherein a capacitor structure is formed on a top of each of the conductive towers.

8. The semiconductor device of claim 7, wherein a top conductive portion of one of the conductive towers, an arm portion of a top conductive layer of the sensing device that is proximate to the one of the conductive towers, and a dielectric layer between the top conductive portion and the top conductive layer form the capacitor structure, wherein the arm portion is located above the top conductive portion.

9. The semiconductor device of claim 8, wherein a dielectric constant of the dielectric layer is greater than a dielectric constant of the insulation layer.

10. The semiconductor device of claim 8, further comprising:
a common conductive line connected to the top conductive portions of the conductive towers, wherein the common conductive line is coupled to a ground terminal.

11. A semiconductor device, comprising:
a substrate including a circuit region and an outer border;
a seal ring formed over the substrate and disposed between the outer border of the substrate and the circuit region;
sensing devices formed over the substrate and disposed between the seal ring and the circuit region;
capacitive metal towers formed over the substrate and positioned proximate to the sensing devices, wherein the capacitive metal towers are configured to provide discharge paths for the sensing devices; and
an insulation layer formed over the substrate, wherein the seal ring, the sensing devices and the capacitive metal towers are formed within the insulation layer.

12. The semiconductor device of claim 11, wherein the seal ring is electrically isolated from the capacitive metal towers.

13. The semiconductor device of claim 11, wherein each of top conductive layers of the sensing devices are connected to adjacent one of top conductive portions of the capacitive metal towers.

14. The semiconductor device of claim 11, wherein the capacitive metal towers are serially connected by a common conductive line, and the common conductive line is coupled to a ground terminal.

15. The semiconductor device of claim 11, wherein a capacitor structure is formed between side surfaces of one of the capacitive metal towers and the sensing device proximate to the one of the metal towers, and the capacitor structure is embedded in the insulation layer.

16. The semiconductor device of claim 11, wherein a capacitor structure is formed on a top of each of the capacitive metal towers, and a dielectric constant of a dielectric layer of the capacitor structure is greater than a dielectric constant of the insulation layer.

17. A method for forming a semiconductor device, comprising:
providing a substrate having a circuit region and a peripheral region around the circuit region;
forming interconnection structures in the peripheral region, wherein the interconnection structures comprises:
a seal ring formed over the substrate;
sensing devices formed over the substrate and disposed between the seal ring and the circuit region; and
conductive towers formed over the substrate and disposed between the seal ring and the sensing devices, wherein the conductive towers are configured to provide discharge paths for the sensing devices; and
forming an insulation layer over the substrate, wherein the seal ring, the sensing devices and the conductive towers are formed in the insulation layer.

18. The method of claim 17, wherein forming the sensing devices comprises:
forming a top conductive layer of each of the sensing devices in contact with adjacent top conductive portion of the conductive towers.

19. The method of claim 17, further comprising:
forming a capacitor structure between a side surface of one of the conductive towers and a side surface of the sensing device proximate to the one of the conductive towers, wherein the capacitor structure is embedded in the insulation layer.

20. The method of claim 17, further comprising:
forming a dielectric layer over a topmost conductive portion of each of the conductive towers, wherein a dielectric constant of the dielectric layer is greater than a dielectric constant of the insulation layer; and
forming a top conductive layer of each of the sensing devices on the dielectric layer, wherein the top conductive layer has an arm portion extends above the topmost conductive portion of each of the conductive towers.
